(19) United States
(12) Patent Application Publication
(10) Pub. No.: US 2022/0285200 A1
(43) Pub. Date: Sep. 8, 2022

(54) TEMPORARY PROTECTIVE FILM, REEL BODY, PACKAGING BODY, PACKAGE BODY, TEMPORARY PROTECTIVE BODY, AND METHOD FOR PRODUCING SEMICONDUCTOR DEVICE

(71) Applicant: Showa Denko Materials Co., Ltd., Chiyoda-ku, Tokyo (JP)

(72) Inventors: Takahiro KURODA, Chiyoda-ku, Tokyo (JP); Tomohiro NAGOYA, Chiyoda-ku, Tokyo (JP); Naoki TOMORI, Chiyoda-ku, Tokyo (JP)

(21) Appl. No.: 17/641,101

(22) PCT Filed: Sep. 17, 2019
(86) PCT No.: PCT/JP2019/036407

§ 371 Date: Mar. 8, 2022

(51) Int. Cl. H01L 21/683; C09J 7/35; H01L 21/56; H01L 23/31; H01L 23/29; H01L 23/495; H01L 23/00; C08J 5/18; C09J 11/06

(52) U.S. Cl. CPC H01L 21/6836; C09J 7/35; H01L 21/565; H01L 21/568; H01L 23/3142; H01L 23/295; H01L 23/49582; H01L 24/48; C08J 5/18; C09J 11/06; H01L 2221/68386; H01L 2221/6834; H01L 2224/48245; H01L 2924/3511; C08J 2333/24

(57) ABSTRACT

A temporary protective film including a support film and an adhesive layer provided on one surface or both surfaces of the support film. The support film is a polyimide film. The thickness of the adhesive layer is less than 8 μm.

### TECHNICAL FIELD

The present invention relates to a temporary protective film, a reel body, a packed body, a packaged body, a temporarily protected body, and a method for producing a semiconductor device.

### BACKGROUND ART

A semiconductor package having a structure in which a sealing layer that seals a semiconductor element mounted on a lead frame on one surface side of the lead frame is formed, and the naked lead frame on the opposite side of the semiconductor element is used for external connection, may be employed on occasions (Patent Literatures 1 and 2). During sealing molding by which a sealing layer is formed in order to produce this semiconductor package, in order to prevent wraparound of a sealing material toward the rear surface of the lead frame on the opposite side of the semiconductor element, the rear surface of the lead frame may be temporarily protected by sticking a temporary protective film thereto. The temporary protective film is usually peeled off from the lead frame after a sealing layer is formed.

### CITATION LIST

### Patent Literature

Patent Literature 1: Japanese Unexamined Patent Publication No. H5-129473

Patent Literature 2: Japanese Unexamined Patent Publication No. H10-12773

### SUMMARY OF INVENTION

### Technical Problem

Along with size reduction and sophistication of semiconductor devices, during the production of a semiconductor device using a temporary protective film that temporarily protects the rear surface of a lead frame, the temporary protective film attached to the lead frame tends to be subjected to thermal history of higher temperatures and longer durations. When the thermal history is increased, problems such as the generation of voids at the interface between the temporary protective film and the lead frame or the like and the lack of peelability of the temporary protective film after sealing molding, tend to become apparent. There is also a possibility that the sealing layer may wrap around the lead frame, with the voids acting as starting points.

An aspect of the present invention relates to a temporary protective film that is used, during sealing molding of forming a sealing layer for sealing a semiconductor element mounted on one surface side of a lead frame, in order to temporarily protect the surface of the lead frame on the opposite side of the semiconductor element. Thereby, the generation of voids occurring concomitantly with sealing molding is suppressed, and also, the peelability after sealing molding is further improved.

### Solution to Problem

According to an aspect of the present invention, there is provided a temporary protective film comprising a support film and an adhesive layer provided on one surface or both surfaces of the support film. The temporary protective film according to the aspect of the present invention is used, during sealing molding of forming a sealing layer that seals a semiconductor element mounted on one surface side of a lead frame having a die pad and an inner lead, in order to temporarily protect a surface of the lead frame, the surface being on the opposite side of the semiconductor element. The support film is a polyimide film. The thickness of the adhesive layer is less than 8 μm.

According to another aspect of the present invention, there is provided a reel body comprising a reel having a cylindrical winding part and the above-described temporary protective film wound around the winding part.

According to still another aspect of the present invention, there is provided a packed body comprising the above-described reel body and a packing bag that accommodates the reel body.

According to still another aspect of the present invention, there is provided a packaged body comprising the above-described packed body and a packaging box accommodating the packed body.

According to still another aspect of the present invention, there is provided a temporarily protected body comprising a lead frame having a die pad and an inner lead; and the above-described temporary protective film. The temporary protective film is attached to the lead frame such that the adhesive layer of the temporary protective film comes into contact with one surface of the lead frame.

According to still another aspect of the present invention, there is provided a method for producing a semiconductor device. The method according to an aspect of the present invention comprises: a step of sticking the above-described temporary protective film to one surface of a lead frame having a die pad and an inner lead, in a direction such that the adhesive layer of the temporary protective film comes into contact with the lead frame; a step of mounting a semiconductor element on a surface of the die pad, the surface being on the opposite side of the temporary protective film; a step of providing a wire that connects the semiconductor element with the inner lead; a step of forming a sealing layer that seals the semiconductor element and the wire and thereby obtaining a sealing-molded body having the lead frame, the semiconductor element, and the sealing layer; and a step of peeling off the temporary protective film from the sealing-molded body, in this order.

### Advantageous Effects of Invention

According to an aspect of the present invention, in connection with a temporary protective film that is used, during sealing molding of forming a sealing layer that seals a semiconductor element mounted on one surface side of a lead frame, in order to temporarily protect a surface of the lead frame, the surface being on the opposite side of the semiconductor element, the generation of voids occurring concomitantly with sealing molding can be suppressed, and also, the peelability after sealing molding can be further improved.

The temporary protective film according to an aspect of the present invention can have excellent characteristics even from the viewpoints of satisfactory adhesiveness to a lead frame during sealing molding, suppression of curling, reduction of warpage of a lead frame, and suppression of adhesive residue.

### BRIEF DESCRIPTION OF DRAWINGS

FIG. 1 is a cross-sectional view illustrating an embodiment of a temporary protective film.

FIG. 2 is a cross-sectional view illustrating an embodiment of a temporary protective film.

FIG. 3 is a perspective view illustrating an embodiment of a reel body.

FIG. 4 is a front view illustrating an embodiment of a packed body.

FIG. 5 is a front view illustrating an embodiment of a packaged body.

FIG. 6 is a cross-sectional view illustrating an embodiment of a method for producing a semiconductor device.

FIG. 7 is a cross-sectional view illustrating an embodiment of a method for producing a semiconductor device.

FIG. 8 is a cross-sectional view illustrating an embodiment of a semiconductor device.

### DESCRIPTION OF EMBODIMENTS

Hereinafter, embodiments of the present invention will be described in detail. However, the present invention is not limited to the following embodiments. The upper limit and the lower limit of a numerical value range described in the present specification can be arbitrarily combined. The numerical values described in the Examples can also be used as the upper limit or the lower limit of a numerical value range.

### Temporary Protective Film

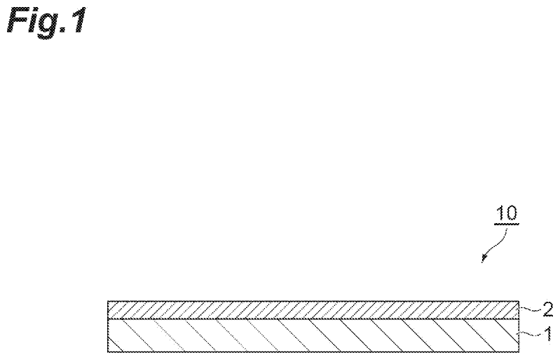

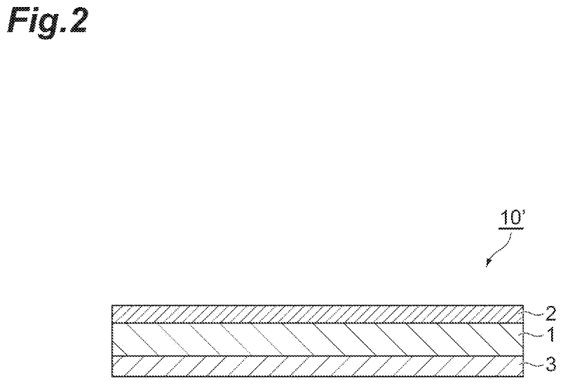

FIG. 1 is a cross-sectional view illustrating a temporary protective film according to an embodiment. The temporary protective film 10 illustrated in FIG. 1 is composed of a support film 1 and an adhesive layer 2 provided on one surface of the support film 1. An adhesive layer may be formed on both surfaces of the support film 1. FIG. 2 is also a cross-sectional view illustrating a temporary protective film according to an embodiment. The temporary protective film 10′ of FIG. 2 has a support film 1; an adhesive layer 2 provided on one of principal surfaces of the support film 1; and a resin layer (non-adhesive layer 3) that is provided on the other principal surface of the support film and substantially does not have adhesiveness. These temporary protective films can be used, in a process for sealing molding of forming a sealing layer that seals a semiconductor element mounted on a lead frame, as a temporary protective film for temporarily protecting a rear surface of a lead frame during sealing molding, by sticking a temporary protective film to the rear surface of the lead frame (surface on the side opposite to the surface where a semiconductor element is mounted).

The support film 1 is a polyimide film and may be particularly an aromatic polyimide film. A polyimide film has high adhesiveness to the adhesive layer 2, together with high heat resistance. When the adhesiveness between the support film 1 and the adhesive layer 2 is high, in a case in which the temporary protective film 10 is peeled off from a lead frame, the support film 1 and the adhesive layer 2 are not easily peeled off.

The glass transition temperature of the support film 1 may be 200° C. or higher or 250° C. or higher, and may be 300° C. or lower.

The coefficient of linear expansion at 20° C. to 200° C. of the support film 1 may be 3.0×10⁻⁵/° C. or lower, 2.5×10⁻⁵/° C. or lower, or 2.0×10⁻⁵/° C. or lower. When the coefficient of linear expansion of the support film 1 is small, warpage of a lead frame to which the temporary protective film 10 is attached tends to be suppressed. The coefficient of linear expansion at 20° C. to 200° C. of the support film is measured using a thermomechanical analyzer (TMA) by a method according to JIS K 7197. The distance between chucks is set to 10 mm.

The shrinkage factor (heat shrinkage factor) obtainable at the time of heating the support film 1 for 60 minutes at 200° C. may be 0.15% or less, 0.13% or less, or 0.10% or less. The heat shrinkage factor can be measured according to JIS K 7133. For the measurement of the heat shrinkage factor, a CNC image analysis system (NEXIV) is used. The heat shrinkage factor can be determined by measuring the difference of the dimensions in the MD direction (longitudinal direction) or the TD direction (direction perpendicular to the MD direction) in the support film before and after a heat treatment. The heat treatment conditions are a temperature of 200° C. and a time of 60 minutes. Between the heat shrinkage factor in the MD direction and the heat shrinkage factor in the . TD direction, the bigger value may be in the above-described range.

The support film 1 may be a surface-treated film. Examples of a method for surface treatment of the support film 1 include chemical treatments such as an alkali treatment and a silane coupling treatment; physical treatments such as a sand mat treatment; a plasma treatment, and a corona treatment. .

The thickness of the support film 1 is not particularly limited; however, the thickness may be 5 to 100 μm, or 5 to 50 μm. When the thickness of the support film 1 is 5 μm or more, there is a tendency that the temporary protective film 10 does not easily form wrinkles. When the thickness of the support film 1 is 100 μm or less, warpage of the lead frame tends to be reduced.

The thickness of the adhesive layer 2 is less than 8 μm. When the thickness of the adhesive layer 2 is less than 8 μm, the generation of voids at the time of sealing molding is suppressed, and also, the peelability of the temporary protective film 10 after sealing molding is further improved. Furthermore, the adhesive strength to a lead frame, which is required during sealing molding, is easily obtained. When the adhesive layer 2 becomes thinner, it is speculated that the generation of outgases caused by heating is suppressed, and as a result, the generation of voids is suppressed. From a similar viewpoint, the thickness of the adhesive layer 2 may be less than 7 μm, less than 6 μm, or less than 5 μm, or may be 0.5 μm or more, 1 μm or more, 2 μm or more, 3 μm or more, or 4 μm or more.

The ratio (T₂/T₁) of the thickness (T₂) of the adhesive layer 2 to the thickness (T₁) of the support film 1 may be 0.2 or less, 0.1 or less, or 0.05 or less. When T₂/T₁ is 0.2 or less, particularly the generation of voids occurring concomitantly with sealing molding tends to be suppressed.

The adhesive layer 2 may contain at least one organic polymer selected from an aromatic polyamide, an aromatic polyester, an aromatic polyimide, an aromatic polyamide-imide, an aromatic polyether, an aromatic polyetheramideimide, an aromatic polyetheramide, an aromatic polyesterimide, and an aromatic polyetherimide.

The adhesive layer 2 may contain an aromatic polyetheramideimide. The aromatic polyetheramideimide may be a polycondensate of a diamine compound including an aromatic diamine having a phenyleneoxy group, and at least one of a tricarboxylic acid or a reactive derivative thereof.

Examples of the aromatic diamine having a phenyleneoxy group, which is used in order to synthesize an aromatic polyetheramideimide, include 2,2 -bis[4-(4-aminophenoxy)phenyl]propane, bis [4-(4-aminophenoxy)phenyl]sulfone, 4,4′-diaminodiphenyl ether, bis[4-(4-aminophenoxy)phenyl] ether, and 2,2 -bis [4-(4-aminophenoxy)]hexafluoropropane.

A combination of an aromatic diamine having a phenyleneoxy group and another diamine compound can also be employed. Examples of the other diamine compound include an aromatic diamine that does not have a phenyleneoxy group, such as 4,4′-methylenebis(2,6-diisopropylamine); a siloxanediamine such as 1,3-bis(3-aminopropyl)-tetramethyldisiloxane; and an α,ω-diaminoalkane such as 1,12-diaminododecane or 1,6-diaminohexane.

The proportion of the aromatic diamine having a phenyleneoxy group in the total amount of the diamine compound that is used in order to synthesize an aromatic polyetheramideimide may be 40 mol % to 100 mol %, or 50 mol % to 97 mol %.

Examples of a tricarboxylic acid and a reactive derivative thereof that are used in order to synthesize an aromatic polyetheramideimide include trimellitic anhydride and trimellitic anhydride chloride.

The adhesive layer 2 may further contain a silane compound having a silyl group and a reactive group. The reactive group may be, for example, an epoxy group, an amino group, or an isocyanate group. The silane compound having an epoxy group is represented by, for example, the following Formula (1).

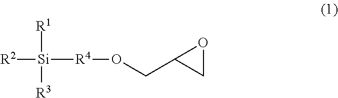

In Formula (1), R¹, R², and R³ each independently represent an alkoxy group having 1 to 3 carbon atoms, an alkyl group having 1 to 6 carbon atoms, or an aryl group having 6 to 12 carbon atoms; and R⁴ represents an alkylene group having 1 to 10 carbon atoms (for example, a propylene group). Examples of the silane compound represented by Formula (1) include 3-glycidoxypropyltrimethoxysilane, 3-glycidoxypropylmethyldimethoxysilane, 3-glycidoxypropyltriethoxysilane, and 3-glycidoxypropylmethyldiethoxysilane.

The content of the silane compound may be 1% to 40% by mass, 1% to 35% by mass, 2% to 35% by mass, 3% to 30% by mass, more than 5% by mass and 35% by mass or less, more than 5% by mass and 30% by mass or less, or more than 5% by mass and 20% by mass or less, with respect to the amount of the organic polymer (for example, aromatic polyetheramideimide). When the content of the silane compound is 1% by mass or more, the peelability of the temporary protective film after the sealing layer is formed tends to be further improved. When the content of the silane compound is 40% by mass or less, since gelation of a varnish, a decrease in the viscosity, and the like do not easily occur, the stability of a varnish is further enhanced, and production of the temporary protective film tends to be further facilitated.

The adhesive layer 2 may further contain other components such as fillers (for example, ceramic powder, glass powder, silver powder, copper powder, resin particles, and rubber particles), coupling agents (provided that agents corresponding to the above-mentioned silane compound are excluded), and peelability imparting agents (for example, a fluorine-based surfactant, a silicone-based mold release agent, and an epoxy-based curing agent). In a case in which the adhesive layer 2 contains a filler, the content of the filler may be 1 to 30 parts by mass, or 5 to 15 parts by mass, with respect to 100 parts by mass of the organic polymer (for example, aromatic polyetheramideimide).

The glass transition temperature of the adhesive layer 2 may be 100° C. to 300° C., 130° C. to 280° C., or 150° C. to 250° C. When the glass transition temperature is 100° C. or higher, the peelability of the adhesive layer 2 after sealing molding tends to be improved. Furthermore, connection failure of wires does not easily occur. On the other hand, when the glass transition temperature is 300° C. or lower, since a decrease in the adhesive strength to a lead frame is suppressed, peeling during a conveyance step, fall-off of a sealing material at the time of sealing, and the like do not easily occur.

The 5% weight reduction temperature of the adhesive layer 2 may be 300° C. or higher, may be 350° C. or higher, and may be 400° C. or higher. When the 5% weight reduction temperature of the adhesive layer 2 is 300° C. or higher, there is a tendency that the lead frame and the wires are not easily contaminated. The 5% weight reduction temperature of the adhesive layer 2 can be measured using a differential thermal balance (manufactured by Seiko Instruments Inc., TG/DTA220) under the conditions of a rate of temperature increase of 10° C./min.

The elastic modulus at 200° C. of the adhesive layer 2 may be 1 MPa or higher, or 3 MPa or higher. When the elastic modulus at 200° C. of the adhesive layer 2 is 1 MPa or higher, softening of the adhesive layer 2 caused by the heat concomitant with wire bonding is suppressed, and therefore, there is a tendency that defective joining of wires does not easily occur. The elastic modulus at 200° C. of the adhesive layer may be 2000 MPa or lower, 1500 MPa or lower, or 1000 MPa or lower. The elastic modulus at 200° C. of the adhesive layer 2 can be measured using a dynamic viscoelasticity measuring apparatus (manufactured by UBM, Rheogel-E4000) under the conditions of a distance between chucks of 20 mm, sinusoidal waves, a rate of temperature increase of 5° C./min, and a tensile mode at a frequency of 10 Hz.

The proportion of a weight reduction caused by heating for 20 minutes at 240° C. at the time of heating the adhesive layer 2 for 10 minutes at 120° C. and then heating for 20 minutes at 240° C., may be less than 0.5% with respect to the weight of the adhesive layer before heating for 20 minutes at 240° C. When the proportion of this weight reduction is small, the generation of outgases caused by heating is small, and therefore, the generation of voids tends to be particularly effectively suppressed. Furthermore, even in a case in which the time in which the temporary protective film 10 is heated is more than 1 hour, there is a tendency that the lead frame and the wire are not easily contaminated. From a similar viewpoint, the proportion of the weight reduction may be less than 0.3%, or less than 0.1%. The lower limit of the proportion of the weight reduction is 0%. The proportion of the weight reduction is measured using a differential thermal balance (manufactured by Seiko Instruments Inc., TG/DTA220) at a rate of temperature increase of 50° C./min.

The non-adhesive layer 3 is a resin layer that substantially does not have adhesiveness (or pressure-sensitive adhesiveness) to a lead frame at 0° C. to 270° C. The non-adhesive layer may be a resin layer that is not easily softened at high temperature, and for example, a resin layer having a high glass transition temperature can function as the non-adhesive layer.

The non-adhesive layer 3 contains an organic polymer. The organic polymer that constitutes the non-adhesive layer 3 may be a thermoplastic resin, a thermosetting resin, or a combination of these. The thermoplastic resin may be, for example, a thermoplastic resin having an amide group, an ester group, an imide group, an ether group, or a sulfone group. The thermosetting resin may be, for example, an epoxy resin, a phenolic resin, a bismaleimide resin (for example, a bismaleimide resin obtained by using bis(4-maleimidophenyl)methane as a monomer), or the like. In the case of combining the thermoplastic resin and the thermosetting resin, the amount of the thermosetting resin may be 5 to 100 parts by mass, or 20 to 70 parts by mass, with respect to 100 parts by mass of the thermoplastic resin. In a case in which the non-adhesive layer 3 contains a thermosetting resin, the non-adhesive layer 3 is usually a cured product formed as the thermosetting resin is cured.

The non-adhesive layer 3 may contain a filler (for example, ceramic powder, glass powder, silver powder, copper powder, resin particles, or rubber particles), a coupling agent, and the like. In a case in which the non-adhesive layer 3 contains a filler, the content of the filler may be 1 to 30 parts by mass, or 5 to 15 parts by mass, with respect to 100 parts by mass of the organic polymer. The content of the coupling agent may be 1 to 20 parts by mass, or 2 to 15 parts by mass, with respect to 100 parts by mass of the organic polymer.

The elastic modulus at 200° C. of the non-adhesive layer 3 may be 10 MPa or higher, 100 MPa or higher, or 1000 MPa or higher. The elastic modulus at 200° C. of the non-adhesive layer 3 can be measured by a method similar to that used for the elastic modulus of the adhesive layer 2.

The 90-degree peel strength obtained by a 90-degree peel test between the non-adhesive layer 3 and a mold may be less than 5 N/m, or 1 N/m or less. This 90-degree peel strength is measured, for example, after the non-adhesive layer 3 is pressure-bonded to a mold made of brass at a temperature of 250° C. and a pressure of 8 MPa for 10 seconds.

The glass transition temperature of the non-adhesive layer 3 may be 150° C. or higher, 200° C. or higher, or 250° C. or higher, and may be 350° C. or lower or 300° C. or lower. When the glass transition temperature of the non-adhesive layer 3 is within these ranges, the non-adhesive layer 3 is not easily softened during sealing molding, and there is a tendency that the non-adhesive layer 3 does not easily stick to the mold and tools.

The thickness of the non-adhesive layer 3 may be 8 μm or less, 7 μm or less, 6 μm or less, or 5 μm or less, and may be 1 μm or more, 2 μm or more, 3 μm or more, 4 μm or more, 5 μm or more, or 6 μm or more.

The temporary protective film 10 can be obtained by, for example, a method including a step of applying a varnish containing an organic polymer (for example, aromatic polyetheramideimide) and a solvent as well as other components such as a silane compound that are used as necessary, on a support film; and a step of forming an adhesive layer 2 by removing the solvent from the coating film. Examples of the solvent include N-methyl-2-pyrrolidone, dimethylacetamide, diethylene glycol dimethyl ether, tetrahydrofuran, cyclohexanone, methyl ethyl ketone, and dimethylformamide. The temporary protective film 10′ further having a non-adhesive layer 3 can be obtained by a method further including a step of applying a varnish on a principal surface of the support film 1 on the opposite side of the adhesive layer 2, and removing the solvent from the coating film.

### Reel Body, Packed Body, and Packaged Body

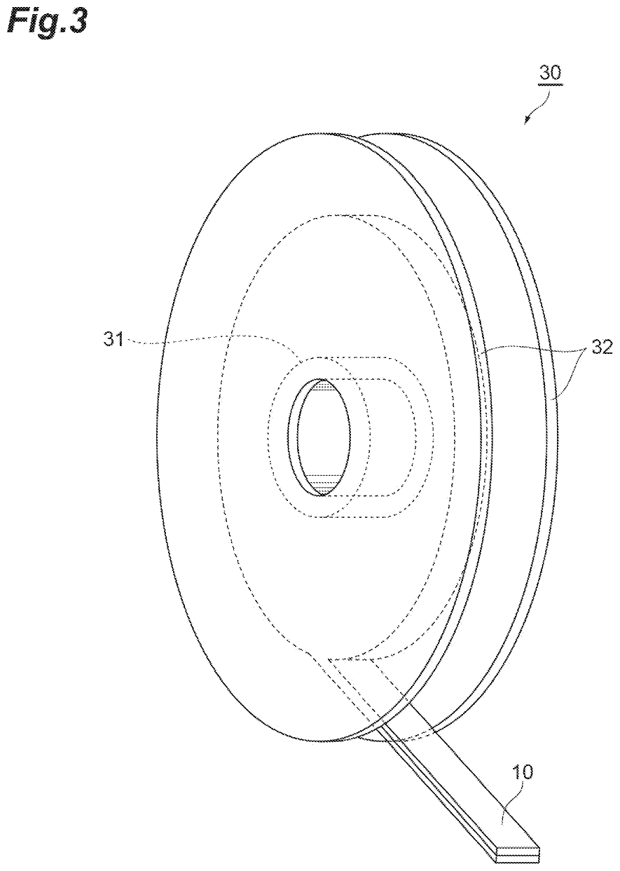

It is also acceptable that a long temporary protective film is wound around a winding core, and while the temporary protective film is wound out from a reel body thus obtained, a semiconductor device is produced. FIG. 3 is a perspective view illustrating an embodiment of a reel body. The reel body 30 illustrated in FIG. 3 comprises a winding core 31; a temporary protective film 10 wound around the winding core 31; and side plates 32.

The width (length in a direction orthogonally intersecting the direction of winding) of the winding core 31 and the temporary protective film 10 may be, for example, 10 μm or more, 50 μm or more, 50 μm or more, or 80 μm or more, and may be 300 μm or less. The width (length in a direction orthogonally intersecting the direction of winding) of the winding core 31 and the temporary protective film 10 may be, for example, 10 μm or more and 300 μm or less, 50 μm or more and 300 μm or less, or 80 μm or more and 300 μm or less.

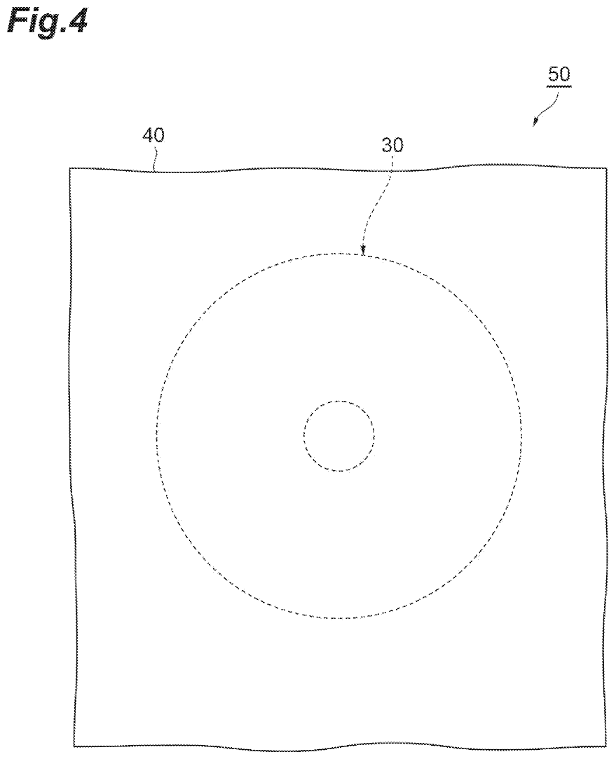

The reel body may be accommodated in a packing bag. FIG. 4 is a front view illustrating an embodiment of a packed body. The packed body 50 illustrated in FIG. 4 comprises a reel body 30 and a packing bag 40 accommodating the reel body 30. One reel body 30 may be accommodated in one packing bag, or a plurality (for example, two or three) reel bodies 30 may be accommodated in one packing bag 40.

The packing bag 40 may be formed from a resin film, and may be formed from a composite film, which is a resin film having an aluminum layer. Specific examples of the packing bag 40 include an aluminum-coated plastic bag and the like. Examples of the material for the resin film include plastics such as polyethylene, polyester, vinyl chloride, and polyethylene terephthalate. The reel body 30 may be accommodated, for example, in a packing bag in a state of being vacuum packed. The packed body 50 is not limited to being vacuum packed.

In the packing bag 40, a desiccant may be accommodated together with the reel body 30. As the desiccant, for example, silica gel may be mentioned. The packed body 50 may further comprise a cushioning material that wraps the packing bag 40 accommodating the reel body 30.

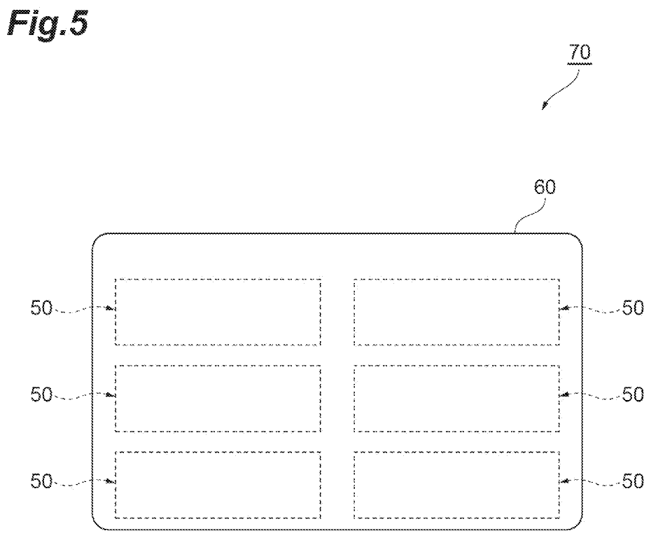

The packed body 50 may be provided as packaged body accommodated in a packaging box. FIG. 5 is a front view illustrating an embodiment of the packaged body. The packaged body 70 illustrated in FIG. 5 comprises a packed body 50 and a packaging box 60 that accommodates the packed body 50. In one packaged box 60, one or a plurality of packed bodies 50 are accommodated. The packaging box 60 may be, for example, a corrugated cardboard box.

### Method for Producing Semiconductor Device

The temporary protective film according to an embodiment can be used, for example, in order to produce a semiconductor device which has a lead frame, a semiconductor element mounted on this, and a sealing layer that seals the semiconductor element on the semiconductor element side of the lead frame, and in which the rear surface of the lead frame is exposed for external connection. The semiconductor device to be produced may be a Non Lead Type Package, and specific examples thereof include quadflat non-leaded package (QFN) and small outline non-leaded package (SON).

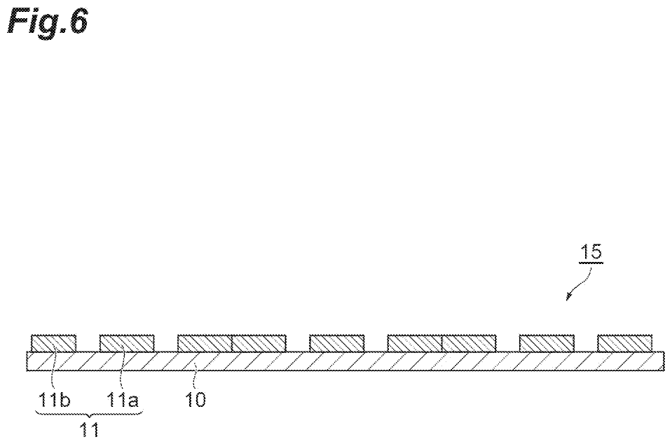

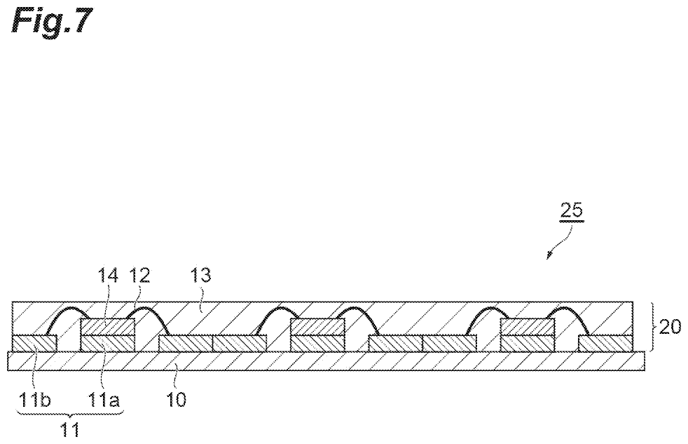

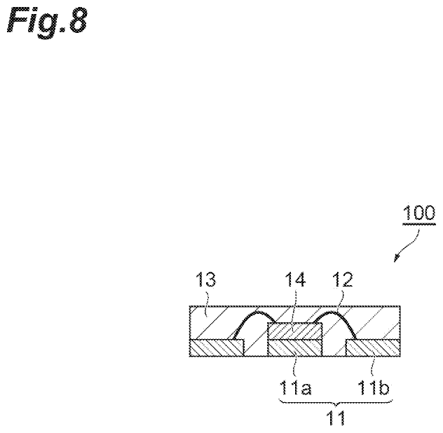

FIG. 6 and FIG. 7 are cross-sectional views illustrating an embodiment of a method for producing a semiconductor device. FIG. 8 is a cross-sectional view illustrating an example of a semiconductor device obtainable by the method of FIG. 6 and FIG. 7.

The method illustrated in FIG. 6 and FIG. 7 comprises: a step of sticking a temporary protective film 10 to one surface (rear surface) of a lead frame 11 having a die pad 11a and an inner lead 11b, in a direction such that the adhesive layer of the temporary protective film comes into contact with the lead frame, and thereby obtaining a temporarily protected body 15 having a lead frame 11 and a temporary protective film 10; a step of mounting a semiconductor element 14 on a surface of the die pad 11a, the surface being on the opposite side of the temporary protective film 10; a step of providing a wire 12 that connects the semiconductor element 14 with the inner lead 11b; a step of forming a sealing layer 13 that seals the semiconductor element 14 and the wire 12, and thereby obtaining a temporarily protected body 25 that has a sealing-molded body 20 having a lead frame 11, a semiconductor element 14, and a sealing layer 13, as well as a temporary protective film 10; and a step of peeling off the temporary protective film 10 from the sealing-molded body 20, in this order.

The lead frame 11 may be, for example, a metal molded body formed using an iron alloy (for example, Alloy 42), copper, or a copper alloy. The lead frame 11 may have a metal molded body containing copper or a copper alloy and a metal coating film that covers the surface of the metal molded body. The metal coating film may contain, for example, palladium, gold, or silver.

Sticking of the temporary protective film 10 to the lead frame 11 can include, for example, laminating the temporary protective film 10 on the lead frame 11 and heating and pressurizing a laminated body comprising the lead frame 11 and the temporary protective film 10.

Lamination of the temporary protective film 10 on the lead frame 11 can be carried out at normal temperature (for example, 5° C. to 35° C.). The method of lamination is not particularly limited; however, for example, the method may be a roll lamination method.

The temperature at which the laminated body comprising the lead frame 11 and the temporary protective film 10 is heated may be, for example, 150° C. to 400° C., 180° C. to 350° C., or 200° C. to 300° C. The pressure that is applied to the laminated body may be, for example, 0.5 to 30 MPa, 1 to 20 MPa, or 3 to 15 MPa. The time for heating and pressurization may be, for example, 0.1 to 60 seconds, 1 to 30 seconds, or 3 to 20 seconds. The laminated body may be preheated before heating and pressurization.

The 90-degree peel strength at 25° C. between the adhesive layer 2 and the lead frame 11 at the time of sticking the temporary protective film 10 to the lead frame 11 such that the adhesive layer 2 comes into contact with the lead frame 11 (hereinafter, may be referred to as “peel strength after sticking”) may be 5 N/m or more, 50 N/m or more, 100 N/m or more, or 150 N/m or more. When the peel strength after sticking is less than 5 N/m, not only the temporary protective film 10 is easily peeled off from the lead frame 11, but also there is a problem such as that a sealing material may infiltrate in between the lead frame 11 and the adhesive layer 2 during sealing molding. The peel strength after sticking may be 2000 N/m or less, 1500 N/m or less, or 1000 N/m or less.

The peeling strength after sticking is measured by, for example, a method of tearing off the temporary protective film with respect to the lead frame in a 90-degree direction according to the 90-degree tear-off method of JIS Z 0237. Specifically, the 90-degree peel strength at the time of tearing off the temporary protective film at a speed of 270 to 330 mm per minute or 300 mm per minute is measured at 25° C.

The peel strength after sticking can be changed depending on the glass transition temperature (Tg) of the adhesive layer 2, the temperature of heating and pressurization, the material of the adherend material, wettability of the adhesive layer 2, and the like. Therefore, in order to adjust the peel strength after sticking to 5 N/m or more, optimal conditions are appropriately selected in consideration of the glass transition temperature (Tg) of the adhesive layer 2, the heating temperature for sticking, the material of the lead frame, wettability of the adhesive layer 2, and the like. Among these, the influence exerted by the glass transition temperature (Tg) of the adhesive layer 2 and the temperature for sticking on the peel strength after sticking is significant. For example, the heating temperature for sticking may be a temperature higher by about 0° C. to 30° C. than the glass transition temperature (Tg) of the adhesive layer 2.

The peel strength after sticking can be measured, for example, using a copper lead frame, a copper lead frame coated with palladium, or a lead frame made of Alloy 42 as the lead frame 11, after the temporary protective film 10 under any of the conditions: (1) a temperature of 230° C., a pressure of 6 MPa, and a time of 10 seconds; (2) a temperature of 350° C., a pressure of 3 MPa, and a time of 3 seconds; or (3) a temperature of 250° C., a pressure of 6 MPa, and a time of 10 seconds.

The semiconductor element 14 is usually mounted on the die pad 11a, with an adhesive (for example, silver paste) interposed therebetween. The adhesive may be cured by means of a heating treatment (for example, 140° C. to 200° C., 30 minutes to 2 hours).

After the semiconductor element 14 is mounted on the die pad 11a, reflow connection (CuClip connection or the like) may be carried out under the conditions of a maximum temperature of 250° C. to 400° C. and 1 to 30 minutes.

The wire 12 is not particularly limited; however, for example, the wire may be a gold wire, a copper wire, or a palladium-coated copper wire. For example, the semiconductor element and the inner lead may be joined with the wire 12 by heating for 3 minutes to 6 hours at 200° C. to 270° C. and also utilizing ultrasonic waves and pressing pressure.

Through sealing molding using a sealing material, a temporarily protected body 25 comprising a sealing-molded body 20 having a plurality of semiconductor elements 14 and a sealing layer 13 that seals those semiconductor elements altogether, is formed. During sealing molding, as the temporary protective film 10 is provided, the sealing material wrapping around to the rear surface side of the lead frame 11 is suppressed.

The temporarily protected body 25 according to an embodiment comprises a lead frame 11 having a die pad 11a and an inner lead 11b; a semiconductor element 14 mounted on the die pad 11a; a wire 12 that connects the semiconductor element 14 and the inner lead 11b; a sealing layer 13 that seals the semiconductor element 14 and the wire 12; and the temporary protective film 10. The adhesive layer 2 of the temporary protective film 10 is attached to the rear surface of the lead frame on the opposite side of the surface where the semiconductor element 14 is mounted.

The temperature during the time of forming the sealing layer 13 may be 140° C. to 200° C., or 160° C. to 180° C. The pressure during the time of forming the sealing layer 13 may be 6 to 15 MPa, or 7 to 10 MPa. The heating time for the sealing molding may be 1 to 5 minutes, or 2 to 3 minutes. The sealing layer 13 can be formed using, for example, a compression mold or a transfer mold.

The sealing layer 13 thus formed may be heated and cured as necessary. The heating temperature for curing the sealing layer 13 may be 150° C. to 200° C., or 160° C. to 180° C. The heating time for curing the sealing layer 13 may be 4 to 7 hours, or 5 to 6 hours.

The sealing material can be selected from those that are usually used as a sealing material of a semiconductor element. For example, the sealing material may contain epoxy resins such as a cresol novolac epoxy resin, a phenol novolac epoxy resin, a biphenyl diepoxy resin, and a naphthol novolac epoxy resin. The sealing material may further contain, for example, additive materials such as a filler, a flame-retardant material such as a bromine compound, and a wax component. An example of a commercially available product of the sealing material is GE-300LC2MA2 (manufactured by Hitachi Chemical Company, Ltd.).

After the sealing molding of forming the sealing layer 13, the temporary protective film 10 is peeled off from the lead frame 11 and the sealing layer 13 of the sealing-molded body 20. In the case of curing the sealing layer 13, the temporary protective film 10 may be peeled off at any time point before or after the curing of the sealing layer 13.

The temperature of peeling off the temporary protective film 10 from the sealing-molded body 20 may be 0° C. to 250° C. When the peel-off temperature is 0° C. or higher, the adhesive layer does not easily remain on the lead frame 11 and the sealing layer 13. When the peel-off temperature is 250° C. or lower, deterioration of the lead frame 11 and the sealing layer 13 tends to be further suppressed. From a similar reason, the peel-off temperature may be 100° C. to 250° C., or 150° C. to 250° C.

When the temporary protective film 10 is attached to the lead frame 11 such that the adhesive layer 2 comes into contact with the lead frame 11, the semiconductor element 14 is mounted on a surface of the die pad, the surface being on the opposite side of the temporary protective film 10, subsequently the semiconductor element 14, the lead frame 11, and the temporary protective film 10 is heated for 3 hours at 240° C., and then a sealing layer 13 that seals the semiconductor element 14 while being in contact with the adhesive layer 2 is formed, the 90-degree peel strength (hereinafter, may be referred to as “peel strength after sealing”) at 180° C. between the adhesive layer 2 and the lead frame 11 as well as the sealing layer 13 may be 600 N/m or less. The peel strength after sealing may be 500 N/m or less, or 450 N/m or less, and may be 0 N/m or more, 3 N/m or more, or 5 N/m or more.

The peel strength after sealing is measured by tearing off the temporary protective film 10 in a 90-degree direction with respect to the lead frame 11 and the sealing layer 13 according to the 90-degree tear-off method of JIS Z 0237. Specifically, the 90-degree peel strength at the time of tearing off the temporary protective film at a rate of 270 to 330 mm per minute, or 300 mm per minute, at 180° C. is measured with a heating 90-degree peel testing machine (manufactured by TESTER SANGYO CO., LTD.). The peel strength after sealing is measured after sealing molding. The sealing molding is carried out, for example, under the conditions of a temperature of 180° C., a pressure of 7 MPa, and a molding time of 2 minutes. Subsequently, the peel strength after sealing may be carried out after the sealing material is cured by heating for 5 hours at 180° C.

The method for producing a semiconductor device may further include, if necessary, a step of removing the adhesive layer (adhesive residue) remaining on the lead frame 11 and the sealing layer 13, after the step of peeling off the temporary protective film 10 from the sealing-molded body 20. The adhesive layer remaining on the lead frame 11 and the sealing layer 13 may also be removed by mechanical brushing, a solvent, or the like. The solvent is not particularly limited; however, the solvent may be N-methyl-2-pyrrolidone, dimethylacetamide, diethylene glycol dimethyl ether, tetrahydrofuran, cyclohexanone, methyl ethyl ketone, dimethylformamide, or the like.

In a case in which the lead frame has a plurality of patterns having a die pad and an inner lead, if necessary, the sealing-molded body 20 is divided, and thereby a plurality of the semiconductor devices 100 of FIG. 8 each having one semiconductor element can be obtained.

That is, in a case in which the lead frame 11 has a plurality of die pads 11a, and a semiconductor element 14 is mounted on each of a plurality of die pads 11a, the production method according to an embodiment may further comprise a step of dividing the sealing-molded body 20 before or after peeling off the temporary protective film 10 (or 10′) from the sealing-molded body 20, and thereby obtaining a semiconductor device 100 having one die pad 11a and a semiconductor element 14.

The semiconductor device produced using the temporary protective film according to an embodiment is excellent in terms of increase in the density, increase in the area, thickness reduction, and the like, and can be suitably utilized in, for example, electronic instruments such as mobile telephones, smart phones, personal computers, and tablets.

### EXAMPLES

Hereinafter, the present invention will be described more specifically by way of Examples; however, the present invention is not intended to be limited to the following Examples.

### 1. Production of Varnish for Forming Adhesive Layer

### Varnish 1

Into a 5000-ml four-necked flask equipped with a thermometer, a stirrer, a nitrogen inlet tube, and a fractionating column, 270.9 g (0.66 mol) of 2,2-bis[-(4-aminophenoxy)phenyl]propane and 8.7 g (0.035 mol) of 1,3-bis(3-aminopropyl)-tetramethyldisiloxane were introduced in a nitrogen atmosphere. These were dissolved in 1950 g of N-methyl-2-pyrrolidone (NMP), and thereby a reaction liquid was prepared. The reaction liquid was cooled to 0° C., and then 149.5 g (0.71 mol) of trimellitic anhydride chloride was added thereto. After trimellitic anhydride chloride was dissolved, 100 g of triethylamine was further added thereto. The reaction liquid was stirred for 2 hours at room temperature, subsequently the temperature was increased to 180° C., and imidation was completed by a reaction for 5 hours. The reaction liquid was introduced into methanol, and polyetheramideimide thus produced was precipitated. Polyetheramideimide thus precipitated was dried and then dissolved in NMP. The solution was introduced into methanol, and polyetheramideimide was precipitated again. Polyetheramideimide thus precipitated was dried under reduced pressure, and thereby a polyetheramideimide in the form of purified powder was obtained. 22 g of the aromatic polyetheramideimide thus obtained and 6.6 g of 3-glycidoxypropyltrimethoxysilane (manufactured by Dow Corning Toray Silicone Co., Ltd., trade name: SH6040) were dissolved in 78 g of NMP, and varnish 1 for forming an adhesive layer was obtained.

### Varnish 2

Into a 1000-ml four-necked flask equipped with a stirrer, a thermometer, a nitrogen gas inlet tube, and a cooling tube, 120.9 g (0.41 mol) of 1,3-bis(3-aminophenoxy)benzene and 44.0 g (0.18 mol) of 1,3-bis(3-aminopropyl)tetramethyldisiloxane were introduced in a nitrogen atmosphere. These were dissolved in 538.3 g of NMP, and thereby a reaction liquid was prepared. The reaction liquid was cooled to 0° C., and then 125.0 g (0.59 mol) of trimellitic anhydride chloride was added thereto. The reaction liquid was stirred for 1 hour at room temperature (25° C.), and then 72.6 g of triethylamine was added thereto. The reaction liquid was stirred for another 1 hour at room temperature (25° C.), and then the reaction liquid was stirred for 6 hours at 180° C. Subsequently, the reaction liquid was introduced into water, and polyetheramideimide thus produced was precipitated. The polyetheramideimide thus precipitated was dried and then was dissolved in NMP. The solution was introduced into water, and polyetheramideimide was precipitated again. The polyetheramideimide thus precipitated was dried under reduced pressure, and a polyetheramideimide in the form of purified powder was obtained. 22 g of the aromatic polyetheramideimide thus obtained and 0.66 g of 3-glycidoxypropyltrimethoxysilane (manufactured by Dow Corning Toray Silicone Co., Ltd., trade name: SH6040) were dissolved in 78 g of NMP, and varnish 2 for forming an adhesive layer was obtained.

### Varnish 3

Into a 5000-ml four-necked flask equipped with a stirrer, a thermometer, a nitrogen inlet tube, and a cooling tube, 253.3 g (0.81 mol) of 1,3-bis(3-aminophenoxy)benzene and 8.7 g (0.035 mol) of 1,3-bis(3-aminopropyl)-tetramethyldisiloxane were introduced in a nitrogen atmosphere. These were dissolved in 1500 g of NMP, and thereby a reaction liquid was prepared. The reaction liquid was cooled to 0° C., and then 239.7 g (1.14 mol) of trimellitic anhydride chloride was added thereto. After the reaction liquid was stirred for 1 hour at room temperature, the temperature was raised to 180° C., and imidation was completed by a reaction for 5 hours. The reaction liquid was introduced into methanol, and polyetheramideimide thus produced was precipitated. The polyetheramideimide thus precipitated was dried and then was dissolved in NMP. The solution was introduced into methanol, and thereby polyetheramideimide was precipitated again. The polyetheramideimide thus precipitated was dried under reduced pressure, and thereby a polyetheramideimide in the form of purified powder was obtained. 22 g of the aromatic polyetheramideimide thus obtained and 6.6 g of 3-ureidopropyltriethoxysilane (50% methanol solution) (manufactured by Shin-Etsu Chemical Co., Ltd., trade name: KBE585) were dissolved in 78 g of NMP, and varnish 3 for forming an adhesive layer was obtained.

### Varnish 4

The following acrylic rubber and epoxy resin were prepared.
Acrylic rubber: WS-023 EK30 (trade name, manufactured by Nagase ChemteX Corporation, weight average molecular weight: 500000 (reference value), glass transition temperature (theoretical value calculated from the copolymerization ratio): −10° C.)
Epoxy resin: EX-614B (trade name, manufactured by Nagase ChemteX Corporation, sorbitol polyglycidyl ether, epoxy equivalent: 174 (reference value))

50 g (30% by mass) of the acrylic rubber, 1.5 g of the epoxy resin, and cyclohexanone were mixed, the mixture was stirred, and varnish 4 in which the concentration of components other than the solvent was 10% by mass was obtained.

### 2. Production of Varnish for Forming Non-Adhesive Layer

### Varnish 5

Into a 5-liter four-necked flask equipped with a thermometer, a stirrer, a nitrogen inlet tube, and a fractionating column, 172.4 g (0.42 mol) of 2,2-bis[4-(4-aminophenoxy)phenyl]propane and 153.7 g (0.42 mol) of 4,4′-methylenebis(2,6-diisopropylaniline) were introduced in a nitrogen atmosphere. These were dissolved in 1550 g of NMP, and thereby a reaction liquid was prepared. The reaction liquid was cooled to 0° C., and then 174.7 g (0.83 mol) of trimellitic anhydride chloride was added thereto. After trimellitic anhydride chloride was dissolved, 130 g of triethylamine was further added thereto. After the reaction liquid was stirred for 2 hours at room temperature (25° C.), the temperature was raised to 180° C., and imidation was completed by a reaction for 5 hours. The reaction liquid was introduced into water, and polyetheramideimide thus produced was precipitated. The polyetheramideimide thus precipitated was dried and then was dissolved in NMP. The solution was introduced into water, and polyetheramideimide was precipitated again. The polyetheramideimide thus precipitated was dried under reduced pressure, and thereby a polyetheramideimide in the form of purified powder was obtained. 120 g of the aromatic polyetheramideimide thus obtained, and 6 g of 3-glycidoxypropyltrimethoxysilane (manufactured by Dow Corning Toray Silicone Co., Ltd., trade name: SH6040) were dissolved in 360 g of NMP, and thereby varnish 5 for forming a non-adhesive layer was obtained.

### 3. Production of Temporary Protective Film

A polyimide film (manufactured by DU PONT-TORAY CO., LTD. trade name: KAPTON EN, coefficient of linear expansion at 20° C. to 200° C. is 1.5×10⁻⁵/° C., shrinkage factor at the time of being heated to 200° C. for 60 minutes is 0.02%) was prepared as a support film. On one surface of the support film, each of the varnishes for forming an adhesive layer as indicated in Table 1 was applied, the coating film was dried, and thereby an adhesive layer was formed. In the case of forming a non-adhesive layer, varnish 5 for forming a non-adhesive layer was applied on the other surface of the support film, the coating film was dried, and thereby a non-adhesive layer was formed. The thicknesses of the adhesive layer and the non-adhesive layer in the temporary protective films of various Examples and Comparative Examples are also presented in Table 1.

### 4. Glass Transition Temperatures of Adhesive Layer and Non-Adhesive Layer

The glass transition temperatures of the various adhesive layers and non-adhesive layers were measured using a thermomechanical analyzer (manufactured by Seiko Instruments Inc., SSC5200 type) in a tensile mode under the conditions of a distance between chucks of 10 mm, a temperature range of 30° C. to 300° C., and a rate of temperature increase of 10° C./min.

TABLE 1

| | Adhesive layer | | | | Non-adhesive layer | | |
|---|---|---|---|---|---|---|---|
| | | Silane | Thick- | | | Thick- | |
| | Var- | compound | ness | Tg | Var- | ness | Tg |
| | nish | (mass %) | (μm) | (° C.) | nish | (μm) | (° C.) |
| Ex. 1 | 1 | SH-6040 | 2 | 230 | — | — | — |
| | | (30 mass %) | | | | | |
| Ex. 2 | 3 | KBE-585 | 3 | 146 | 5 | 2 | 253 |
| | | (15 mass %) | | | | | |
| Ex. 3 | 1 | SH-6040 | 7 | 230 | 5 | 5 | 253 |
| | | (30 mass %) | | | | | |
| Ex. 4 | 2 | SH-6040 | 1 | 187 | — | — | — |
| | | (3 mass %) | | | | | |
| Ex. 5 | 2 | SH-6040 | 5 | 187 | 5 | 3 | 253 |
| | | (3 mass %) | | | | | |
| Ex. 6 | 3 | KBE-585 | 6 | 146 | — | — | — |
| | | (15 mass %) | | | | | |
| Comp. | 2 | SH-6040 | 10 | 187 | 5 | 8 | 253 |
| Ex. 1 | | (3 mass %) | | | | | |
| Comp. | 4 | — | 2 | −10 | — | — | — |
| Ex. 2 | | | | | | | |
| Comp. | 3 | KBE-585 | 15 | 146 | 5 | 12 | 253 |
| Ex. 3 | | (15 mass %) | | | | | |
| Comp. | 1 | SH-6040 | 20 | 230 | 5 | 15 | 253 |
| Ex. 4 | | (30 mass %) | | | | | |

### 5. Proportion of Weight Reduction Caused by Heating

The weight reduction at the time of heating the adhesive layer of the temporary protective films of various Examples and Comparative Examples in the order of 10 minutes at 120° C. and 20 minutes at 240° C. was measured. When the weight after heating for 10 minutes at 120° C. is designated as W0, and the weight after heating for 20 minutes at 240° C. is designated as W1, the weight reduction is a value calculated by the following formula.

Proportion (%) of weight reduction={(W0−W1)/W0}×100

### 6. 90-Degree Peel Strength

### (1) After Sticking

The following lead frame having a die pad and an inner lead was prepared.
Cu: Copper lead frame (50 mm×200 mm)
PPF: Copper lead frame coated with palladium (50 mm×200 mm)

To the lead frame of Cu or the lead frame of PPF, the adhesive layer of each temporary protective film was attached under the attaching conditions shown in Table 2. In the case of the temporary protective film of Comparative Example 2, since the adhesive layer had tackiness at normal temperature (25° C.), the temporary protective film was attached to the lead frame at normal temperature using a hand roller under the conditions of a load of 20 N. The combination of the lead frame and the temporary protective film was as shown in Table 2. Through a 90-degree peel test of tearing off the temporary protective film from the lead frame (speed of tear-off: 300 mm per minute), the 90-degree peel strength at 25° C. between the adhesive layer and the lead frame was measured.

### (2) After Sealing

To the die pad of each lead frame to which a temporary protective film was attached, a semiconductor element was adhered using a silver paste. The silver paste was cured by heating for 60 minutes at 180° C. Subsequently, a gold wire as a wire was connected to the semiconductor element and the inner lead by heating for 3 hours at 240° C. Next, a sealing layer that sealed the semiconductor element was formed using a sealing material (GE-300LC2MA2, manufactured by Hitachi Chemical Company, Ltd.) under the conditions of a temperature of 180° C., a pressure of 7 MPa, and a heating time of 2 minutes. After sealing molding, the 90-degree peel strength at 180° C. was measured by a 90-degree peel test (speed of tear-off: 300 mm per minute) of tearing off the temporary protective film from the lead frame and the sealing layer.

TABLE 2

| | Adhe- | Weight | | | 90-degree peel | |
|---|---|---|---|---|---|---|
| | sive | reduction | | | strength | |
| | layer | 220° C. × | | | [N/m] | |
| | Thick- | 20 | | | After | After |
| | ness | minutes | Sticking | Lead | sticking/ | sealing/ |
| | (μm) | (mass %) | conditions | frame | 25° C. | 180° C. |
| Ex. 1 | 2 | 0.02 | 250° C./8 | Cu | 35 | 450 |
| | | | MPa/10 s | | | |
| Ex. 2 | 3 | 0.04 | 190° C./6 | Cu | 80 | 430 |
| | | | MPa/10 s | | | |
| Ex. 3 | 7 | 0.05 | 250° C./8 | Cu | 50 | 360 |
| | | | MPa/10 s | | | |
| Comp. | 10 | 0.55 | 230° C./6 | Cu | 400 | 680 |
| Ex. 1 | | | MPa/10 s | | | |
| Comp. | 2 | 1.45 | Normal | Cu | 25 | 10 |
| Ex. 2 | | | temperature | | | |
| | | | Hand roller | | | |
| Ex. 4 | 1 | 0.03 | 230° C./6 | PPF | 80 | 440 |
| | | | MPa/10 s | | | |
| Ex. 5 | 5 | 0.06 | 230° C./6 | PPF | 200 | 350 |
| | | | MPa/10 s | | | |
| Ex. 6 | 6 | 0.08 | 190° C./6 | PPF | 75 | 390 |
| | | | MPa/10 s | | | |
| Comp. | 15 | 0.58 | 190° C./6 | PPF | 180 | 800 |
| Ex. 3 | | | MPa/10 s | | | |
| Comp. | 20 | 0.70 | 250° C./8 | PPF | 60 | 610 |
| Ex. 4 | | | MPa/10 s | | | |

As shown in Table 2, the temporary protective films of Examples exhibited relatively high 90-degree peel strengths after sticking, and also exhibited relatively low 90-degree peel strengths to the extent of being peelable after sealing. Sealing-molded bodies thus formed were observed, and in the case of Examples, the generation of voids occurring concomitantly with sealing molding was not recognized. Since the temporary protective films of Comparative Examples 1, 3, and 4 having a 90-degree of peel strength after sealing of more than 600 N/m were fractured at the time of peeling from the lead frame after sealing, the temporary protective films could not be torn off from the sealing-molded bodies.

### REFERENCE SIGNS LIST

1: support film, 2: adhesive layer, 3: non-adhesive layer, 10, 10′: temporary protective film, 11: lead frame, 11a: die pad, 11b: inner lead, 12: wire, 13: sealing layer, 14: semiconductor element, 15: temporarily protected body, 20: sealing-molded body, 25: temporarily protected body, 30: reel body, 31: winding core, 32: side plates, 40: packing bag, 50: packed body, 70: packaged body, 100: semiconductor device.

1. A temporary protective film comprising:
a support film; and
an adhesive layer provided on one surface or both surfaces of the support film,
wherein the support film is a polyimide film, and
a thickness of the adhesive layer is less than 8 μm.

2. The temporary protective film according to claim 1, wherein the thickness of the adhesive layer is less than 5 μm.

3. The temporary protective film according to claim 1, wherein the adhesive layer comprises at least one organic polymer selected from an aromatic polyamide, an aromatic polyester, an aromatic polyimide, an aromatic polyamideimide, an aromatic polyether, an aromatic polyetheramideimide, an aromatic polyetherimide, an aromatic polyesterimide, and an aromatic polyetherimide.

4. The temporary protective film according to claim 3, wherein the adhesive layer further comprises a silane compound represented by the following Formula (1): 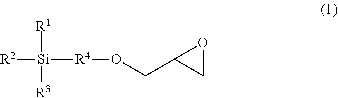
wherein R¹, R², and R³ each independently represent an alkoxy group having 1 to 3 carbon atoms, an alkyl group having 1 to 6 carbon atoms, or an aryl group having 6 to 12 carbon atoms; and R⁴ represents an alkylene group having 1 to 10 carbon atoms.

5. The temporary protective film according to claim 1, wherein when the adhesive layer is heated for 10 minutes at 120° C. and then heated for 20 minutes at 240° C., a proportion of weight reduction caused by heating for 20 minutes at 240° C. is less than 0.5% with respect to the weight of the adhesive layer before heating for 20 minutes at 240° C.

6. The temporary protective film according to claim 1, wherein the adhesive layer is configured to have a 90-degree peel strength, between the adhesive layer and a lead frame as well as a sealing layer, of 600 N/m or less at 180° C. when the temporary protective film is attached to a lead frame having a die pad and an inner lead such that the adhesive layer comes into contact with the lead frame, a semiconductor element is mounted on a surface of the die pad, the surface being on the opposite side of the temporary protective film, subsequently the semiconductor element, the lead frame, and the temporary protective film are heated for 3 hours at 240° C., and then a sealing layer that seals the semiconductor element while being in contact with the adhesive layer is formed.

7. The temporary protective film according to claim 1, wherein the temporary protective film further comprises a non-adhesive layer, and
the adhesive layer is provided on one principal surface of the support film, while the non-adhesive layer is provided on the other principal surface of the support film.

8. A reel body comprising:
a reel having a winding core; and
the temporary protective film according to claim 1
wound around the winding core.

9. A packed body comprising:
the reel body according to claim 8; and
a packing bag, the packing bag accommodating the reel body.

10. The packed body according to claim 9, further comprising a desiccant accommodated in the packing bag.

11. The packed body according to claim 9, further comprising a cushioning material that wraps the packing bag.

12. A packaged body comprising the packed body according to claim 9 and a packaging box accommodating the packed body.

13. A temporarily protected body comprising:
a lead frame having a die pad and an inner lead; and
the temporary protective film according to claim 1,
wherein the temporary protective film is attached to the lead frame such that the adhesive layer of the temporary protective film comes into contact with one surface of the lead frame.

14. The temporarily protected body according to claim 13, further comprising:
a semiconductor element mounted on the die pad;
a wire that connects the semiconductor element with the inner lead; and
a sealing layer that seals the semiconductor element and the wire.

15. The temporarily protected body according to claim 13, wherein the lead frame has a metal molded body comprising copper or a copper alloy; and a metal coating film that coats a surface of the metal molded body.

16. A method for producing a semiconductor device, the method comprising:
sticking the temporary protective film according to claim 1 to one surface of a lead frame having a die pad and an inner lead, in a direction such that the adhesive layer of the temporary protective film comes into contact with the lead frame;
mounting a semiconductor element on a surface of the die pad, the surface being on the opposite side of the temporary protective film;
providing a wire that connects the semiconductor element with the inner lead;
forming a sealing layer that seals the semiconductor element and the wire and thereby obtaining a sealing-molded body having the lead frame, the semiconductor element, and the sealing layer; and
peeling off the temporary protective film from the sealing-molded body.

17. The method according to claim 16, wherein the lead frame has a plurality of the die pads, the semiconductor element is mounted on each of the plurality of die pads, and
the method further comprises dividing the sealing-molded body before or after peeling off the temporary protective film from the sealing-molded body, and thereby obtaining a semiconductor device having a pair of the die pad and the semiconductor element.

18. The method according to claim 16, wherein the lead frame has a metal molded body comprising copper or a copper alloy, and a metal coating film that coats a surface of the metal molded body.
